(19) United States
(12) Patent Application Publication
(10) Pub. No.: US 2007/0172988 A1
(43) Pub. Date: Jul. 26, 2007

(54) Microstructure manufacturing method and microstructure

(75) Inventors: Tadashi Nakatani, Kawasaki (JP); Anh Tuan Nguyen, Kawasaki (JP); Satoshi Ueda, Kawasaki (JP); Yu Yonezawa, Yokohama-shi (JP); Naoyuki Mishima, Yokohama-shi (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignees: FUJITSU LIMITED, Kawasaki (JP); FUJITSU MEDIA DEVICES LIMITED, Yokohama-shi (JP)

(21) Appl. No.: 11/656,390

(22) Filed: Jan. 23, 2007

(30) Foreign Application Priority Data
Jan. 24, 2006 (JP) 2006-015139

(51) Int. Cl. H01L 21/00

(52) U.S. Cl. 438/113

(57) ABSTRACT

A microstructure, suitable for avoiding sticking phenomena, includes a base, a first structural portion joined to the base, and a second structural portion opposed to the base and having a fixed end fixed to the first structural portion. Such a microstructure is made by a method including the step of processing a material substrate having a stacked structure made of a first layer, a second layer, and an intermediate layer between the first and second layers. By this method, the first layer is formed with the first structural portion, the second structural portion having the fixed end fixed to the first structural portion, and a support beam bridging the first and second structural portions. Thereafter, wet etching is performed to remove a region of the intermediate layer between the second layer and the second structural portion, followed by a drying step, and a cutting step with respect to the support beam.

### BACKGROUND OF THE INVENTION

1. Field of the Invention

The present invention relates to a microstructure manufacturing method utilizing MEMS technology, and also to a microstructure manufactured utilizing MEMS technology.

2. Description of the Related Art

In the field of portable telephones and other wireless communication equipment, increases in the number of mounted components in order to realize more sophisticated functions have been accompanied by demands for miniaturization of high-frequency circuits and RF circuits. In order to respond to such demands, efforts have been in progress for the miniaturization of various components comprised by circuits using MEMS (micro-electromechanical systems) technology.

MEMS switches are well-known as microstructures manufactured using MEMS technology. A MEMS switch is a switching device each of the components of which are formed to be very fine, and has at least one pair of contacts which are mechanically opened and closed to execute switching, and a driving mechanism to achieve mechanical open/close operation of the contact pair. MEMS switches tend to exhibit higher insulating properties in the open state, and a lower insertion loss in the closed state, than such switches as PIN diodes and MESFETs, particularly in high-frequency switching in the GHz range. This is because an open state is achieved through mechanical separation of the contact pair, and because there is little stray capacitance due to the fact that the switching is mechanical. MEMS switching is for example described in Japanese Patent Laid-open H09-17300, Japanese Patent Laid-open H11-17245, and Japanese Patent Laid-open 2001-143595.

FIG. 30 and FIG. 31 show a microswitching device X2, which is an example of MEMS switches of the prior art. FIG. 30 is a partial plane view of the microswitching device X2, and FIG. 31 is a cross-sectional view along line XXXI-XXXI in FIG. 30.

The microswitching device X2 comprises a base S2, fixed portion 41, movable portion 42, contact electrode 43, pair of contact electrodes 44, and driving electrodes 45 and 46. The fixed portion 41 is joined to the base S2. The movable portion 42 extends from the fixed portion 41 along the base S2. The contact electrode 43 is provided on the side of the movable portion 42 opposing the base S2. The driving electrode 45 is provided on the movable portion 42 and on the fixed portion 41. The pair of contact electrodes 44 are formed in a pattern on the base S2 so as to be in opposition to one end of the contact electrode 43. The driving electrode 46 is provided at a position corresponding to the driving electrode 45 on the base S2, and is connected to ground. On the base S2 is formed a prescribed wiring pattern (not shown), electrically connected to the contact electrode 44 or to the driving electrode 46.

In a microswitching device X2 configured in this way, when a prescribed potential is applied to the driving electrode 45, an electrostatic attractive force arises between the driving electrodes 45 and 46. As a result, the movable portion 42 is elastically deformed to the position at which the contact electrode 43 makes contact with both the contact electrodes 44. In this way, the closed state of the microswitching device X2 is achieved. In the closed state, the pair of contact electrodes 44 is electrically bridged by the contact electrode 43, so that current is permitted to pass between the contact electrode pair 44.

On the other hand, when the microswitching device X2 is in the closed state, if the electrostatic attractive force acting on the driving electrodes 45 and 46 is annihilated, the movable portion 42 returns to its natural state, and the contact electrode 43 is isolated from the contact electrodes 44. In this way, as shown in FIG. 31, the open state of the microswitching device X2 is achieved. In the open state, the pair of contact electrodes 44 are electrically separated, and the passage of current between the contact electrode pair 44 is impeded.

FIG. 32 and FIG. 33 show a first method of manufacture of a microswitching device X2. In this method, as shown in FIG. 32(a), the contact electrodes 44 and driving electrode 46 are formed by patterning on the base S2. Specifically, a prescribed conductive material is deposited in a film on the base S2, after with a photolithography method is used to form a prescribed resist pattern on the conductive film, and the resist pattern is used as a mask to perform etching of the conductive film. Next, as shown in FIG. 32(b), a sacrificial layer 47 is formed. Specifically, for example a sputtering method is used to deposit or grow a prescribed material on the base S2, while covering the pair of contact electrodes 44 and the driving electrode 46, after which the material film is patterned. Then, a prescribed mask is used to perform etching, to form one depression 47a at a location corresponding to the pair of contact electrodes 44 in the sacrificial layer 47, as shown in FIG. 32(c). Next, by filling the depression 47a with a prescribed material, the contact electrode 43 is formed, as shown in FIG. 32(d).

Next, as shown in FIG. 33(a), a material film 48 is formed, extending over the sacrificial layer 47 and over the base S2. Then, as shown in FIG. 33(b), the driving electrode 45 is formed by patterning on the material layer 48. Specifically, after forming a film of a prescribed conductive material on the material film 48, a photolithography method is used to form a prescribed resist pattern on the conductive film, and the resist pattern is used as a mask to perform etching of the conductive film. Next, as shown in FIG. 33(c), by patterning the material film 48, a fixed portion 41 and movable portion 42 are formed. Specifically, after forming a prescribed resist pattern on the material film 48 by a photolithography method, the resist pattern is used as a mask to etch the material film 48. Then, as shown in FIG. 33(d), the sacrificial layer 47 is partially removed. Specifically, while undercutting below the movable portion 42, etching of the sacrificial layer 47 is performed using a prescribed etching liquid so as to leave a portion of the sacrificial layer 47 below the fixed portion 41, utilizing the fixed portion 41 and movable portion 42, which function as etching masks. In this way, each portion of the microswitching device X2 is formed. After wet etching, a drying process is performed to dry the device.

In this drying process, there are cases in which a method (called the alcohol drying method) is adopted, in which etching liquid adhering to the device surface is replaced with water or another first rinsing liquid; the first rinsing liquid is replaced with a second rinsing liquid, such as alcohol; and then, nitrogen gas is blown onto the surface, or other means are used to cause the second rinsing liquid to evaporate. However, when using such an alcohol drying method, a “sticking” phenomenon tends to occur (the rate of occurrence of sticking is approximately 60%), in which the movable portion 42 or contact electrode 43 permanently adheres to the base S2 or to the contact electrodes 44. When using the alcohol drying method, as the drying process proceeds, the volume of the second rinsing liquid which has once entered into the gap between the base S2 and the movable portion 42 gradually decreases, and due to the action of surface tension of the second rinsing liquid, the movable portion 42 adheres to the base S2. In such cases, the movable portion 42 or contact electrode 43 may be in contact with the base S2 or contact electrodes 44. In the state of contact, van der Waals forces, electrostatic forces and similar act at the point of contact, and this is thought to result in the sticking phenomenon. A microswitching device X2 in which such a sticking phenomenon has occurred cannot be used as a switching device.

As a technique for suppressing the occurrence of this sticking phenomenon while performing drying, the freeze-drying method is known. In the freeze-drying method, for example, the etching liquid used in the above-described wet etching is ultimately replaced by cyclohexane, and after freezing this cyclohexane, the cyclohexane is sublimated. However, for practical purposes it is difficult to completely avoid the sticking phenomenon by means of the freeze-drying method. That is, the sticking phenomenon occurs with a certain probability. In addition, when using the freeze-drying method there is the possibility of damaging components of the device during freezing.

Another method of performing drying while suppressing the sticking phenomenon is the supercritical drying method. In the supercritical drying method, for example, etching liquid used in the above-described wet etching is ultimately replaced with liquefied carbon dioxide in a prescribed chamber, and the carbon dioxide is pressurized and heated to bring it to the supercritical state, and is then cooled. However, in the supercritical drying method it is difficult to completely avoid the sticking phenomenon. In addition, it is difficult to perform efficient drying using the supercritical drying method, and so adoption of the supercritical drying method may result in decreased device manufacturing efficiency.

FIG. 34 shows a portion of the processes in a second method of manufacture of microswitching devices X2. First, similarly to the procedure explained above in the first manufacturing method referring to FIG. 32(a) to FIG. 33(c), the contact electrodes 44, driving electrode 46, sacrificial layer 47, contact electrode 43, driving electrode 45, fixed portion 41, and movable portion 42 are formed on the base S2, as shown in FIG. 34(a). Next, as shown in FIG. 34(b), a sacrificial bridge film 47′ is formed, bridging the base S2 and movable portion 42. Specifically, after forming a film of a prescribed photoresist, which can be removed by dry etching, across the base S2, fixed portion 41, and movable portion 42, the photoresist film is patterned to form the sacrificial bridge film 47′. Next, as shown in FIG. 34(c), wet etching is performed to partially remove the sacrificial bridge 47. Specifically, a procedure is performed similar to that described above in the first manufacturing method, referring to FIG. 33(d). After the wet etching, a drying process is performed. Then, as shown in FIG. 34(d), the sacrificial bridge film 47′ is etched and removed by dry etching. In this way, each portion of the microswitching device X2 is formed.

When performing the drying process after wet etching in this second manufacturing method, the sacrificial bridge film 47′ bridges the base S2 and movable portion 42 as shown in FIG. 34(c). Hence even when the above-described alcohol drying method is employed as the drying method, there are cases in which the sacrificial bridge film 47′ supports the movable portion 42 and drawing of the movable portion 42 to the side of the base S2 is impeded. Hence there are cases in which the sticking phenomenon can be avoided.

However, the sacrificial bridge film 47′ is originally separate from the base S2 and from the movable portion 42, and so there are cases in which inadequate joining strength is obtained between the sacrificial bridge film 47′ and the movable portion 42 in particular. In addition, the sacrificial bridge film 47′ is a thin film of photoresist, and so there are cases in which adequate mechanical strength (bending strength and similar) cannot be obtained from the sacrificial bridge film 47′ itself. Hence there are cases in which the sacrificial bridge film 47′ cannot adequately support the movable portion 42, drawn toward the base S2 during the drying process after wet etching. From the standpoint of reducing the driving voltage, a large-area driving electrode 45 is desired, and so there is a tendency for large-size movable portions 42 to be sought; when using a sacrificial bridge portion 47′, the larger the size of the movable portion 42 (that is, the greater the surface tension of the rinsing liquid acting so as to draw the movable portion 42 toward the base S2 during the drying process), the harder it is to appropriately support the movable portion 42 such that the sticking phenomenon does not occur in the drying process.

### SUMMARY OF THE INVENTION

This invention was devised in light of the above circumstances, and has as an object the provision of a microstructure manufacturing method and a microstructure suitable for avoiding the sticking phenomenon.

According to a first aspect of the invention, a method is provided for the manufacture of a microstructure, comprising a base, a first structural portion joined to the base, and a second structural portion having a fixed end fixed to the first structural portion and which is opposed to the base, by performing processing of a material substrate having a stacked structure, comprising a first layer, a second layer, and an intermediate layer between the first layer and second layer. This manufacturing method comprises a formation process of forming, in the first layer, the first structural portion, the second structural portion having a fixed end fixed at the first structural portion, and a support beam bridging the first and second structural portions; a wet etching process of removing, by wet etching, a region of the intermediate layer between the second layer and the second structural portion; a drying process; and a cutting process of cutting the support beam.

In the microstructure manufacturing of the first aspect of the invention, in a state in which the support beam bridges the first structural portion joined to the base and the second structural portion having a fixed end fixed at the first structural portion and which is not joined to but is opposed to the base, the wet etching process and the subsequent drying process are performed. The support beam which bridges the first structural portion and second structural portion is created in a first layer of the material substrate by a formation process, similarly to the first and second structural portions. That is, the support beam is integral and continuous with the first and second structural portions. In such a support beam, high strength can easily be achieved for bridging of the first and second structural portions. Consequently, the above-described alcohol drying method, for example, is appropriate as the drying process for the support beam in this invention, with respect to supporting the second structural portion and impeding improper deformation of the second structural portion (for example, with attraction toward the base of the second structural portion impeded). Thus the present manufacturing method is appropriate for avoiding the sticking phenomenon when manufacturing a prescribed microstructure.

According to a second aspect of the invention, a method is provided for the manufacture of a microstructure, comprising a base, a first structural portion joined to the base, a second structural portion having a fixed end fixed to the first structural portion and which is opposed to the base, a first electrode provided on the side of the second structural portion opposite the base, and a second electrode, having a region opposed to the first electrode, and joined to the first structural portion, by performing processing of a material substrate having a stacked structure, comprising a first layer, a second layer, and an intermediate layer between the first layer and second layer. This manufacturing method comprises a formation process of forming, in the first layer, the first electrode on a region to be processed to form the second structural portion; a formation process of forming, in the first layer, the first structural portion, the second structural portion having a fixed end fixed at the first structural portion, and a support beam bridging the first and second structural portions; a process of forming a sacrificial layer, having an opening portion to expose the second electrode joining area in the first structural portion and covering the side of the first layer; a second electrode formation process of forming the second electrode, having a region opposing the first electrode with the sacrificial layer intervening, and joined to the first structural portion in the second electrode joining area; a process of removing, by wet etching, the sacrificial layer and a region of the intermediate layer between the second layer and the second structural portion; a drying process; and a cutting process of cutting the support beam. By means of this manufacturing method, a microstructure comprising a second structural portion as a movable portion (for example, a microswitching device) can be manufactured.

In the microstructure manufacturing of the second aspect of the invention, in a state in which the support beam bridges the first structural portion joined to the base and the second structural portion having a fixed end fixed at the first structural portion and which is not joined to but is opposed to the base, the wet etching process and the subsequent drying process are performed. The support beam which bridges the first structural portion and second structural portion is created in a first layer of the material substrate by a formation process, similarly to the first and second structural portions. That is, the support beam is integral and continuous with the first and second structural portions. In such a support beam, high strength can easily be achieved for bridging of the first and second structural portions. Consequently, the support beam according to this invention is appropriate in the case where the above-described alcohol drying method, for example, is employed in the drying process, with respect to supporting the second structural portion and impeding the drawing of the second structural portion toward the base, or with respect to supporting the second structural portion and impeding the drawing of the second structural portion toward the second electrode. Thus the present manufacturing method is appropriate for avoiding the sticking phenomenon when manufacturing a prescribed microstructure.

In the first and second aspects of the invention, it is preferable that in the cutting process the support beam be cut using reactive ion etching (RIE). RIE, which is an anisotropic dry etching method, is appropriate as a method for cutting the support beam while leaving the first and second structural portions.

In the second aspect of the invention, it is preferable that in the cutting process the support beam be cut by reactive ion etching, and that the first electrode and second electrode are made of a material having resistance to the reactive ion etching. By means of this configuration, there is no need to provide a protective film to protect the first and second electrodes prior to the cutting process.

In the second aspect of the invention, it is preferable that in the formation process the support beam be formed at a position not opposed to the second electrode. Or, an opening portion may be provided in the second electrode, and in the formation process the support beam may be formed at a position opposing the opening portion.

It is preferable that the support beam have a width of 0.3 to 50 μm, and more preferable that the support beam have a width of 0.3 to 2 μm. It is preferable that prior to the cutting process, the second structural portion have a thickness of 3 μm or greater (in other words, no smaller than 3 μm). These configurations are suitable for cutting the support beam while leaving the first and second structural portions.

In a preferred aspect, in the formation process the first layer is subjected to anisotropic etching (for example RIE) through a mask pattern to mask regions which are to be processed into the first structural portion, second structural portion, and support beam in the first layer. By this means, a support beam bridging the first and second structural portions can be formed appropriately.

In another preferred aspect, the manufacturing method further comprises a process prior to the formation process of forming, on the first layer, an etching amount adjustment film, corresponding to the region in the first layer to be processed into the support beam, and in the formation process, anisotropic etching (for example RIE) is performed on the etching amount adjustment film together with the first layer through the mask pattern for masking regions in the first layer which are to be processed into the first structural portion and second structural portion. By means of this configuration, a support beam can be appropriately formed which is thinner than the first and second structural portions (of thickness 1 to 3 μm, for example), and which bridges the first and second structural portions.

It is preferable that the first layer comprise single-crystal silicon. Such a configuration is suitable for obtaining a support beam with high strength.

It is preferable that the etching amount adjustment film comprise silicon oxide or silicon nitride. Such a configuration is suitable for adjusting the thickness of the support beam in the above-described other preferred aspect.

A microstructure of a third aspect of the invention is provided. This microstructure comprises a base, a first structural portion joined to the base, a second structural portion having a fixed end fixed to the first structural portion and opposing the base, and a support beam which bridges the first structural portion and second structural portion. It is preferable that this microstructure further comprise a first electrode, provided on the side of the second structural portion opposite the base, and a second electrode, having a region opposing the first electrode, and joined to the first structural portion. This microstructure is equivalent to an intermediate manufactured object in the manufacturing method of the first or second aspect of the invention, prior to the cutting process.

In the third aspect of the invention, it is preferable that the second electrode have an opening portion at a location opposing the gap between the fixed portion and the movable portion. Such a configuration is suitable for use when forming numerous support beams in the manufacturing method of the first aspect or the second aspect.

In the third aspect of the invention, it is preferable that the support beam have a thickness of 0.3 to 50 μm, and more preferable that the support beam have a width of 0.3 to 2 μm. It is preferable that the support beam be thinner than the first structural portion and the second structural portion. It is preferable that the second structural portion have a maximum-thickness portion of 3 μm or greater. Such a configuration is suitable for cutting the support beam while leaving the first and second structural portions in the manufacturing methods of the first and second aspects.

### BRIEF DESCRIPTION OF THE DRAWINGS

FIG. 1 is a plane view of a microswitching device manufactured by a microstructure manufacturing method of the invention;

FIG. 2 is a partial plane view of the microswitching device of FIG. 1;

FIG. 3 is a cross-sectional view along line III-III in FIG. 1;

FIG. 4 is a cross-sectional view along line IV-IV in FIG. 1;

FIG. 5 is a cross-sectional view along line V-V in FIG. 1;

FIG. 6 shows a portion of the processes in the microstructure manufacturing method of the first aspect of the invention;

FIG. 7 shows processes following those of FIG. 6;

FIG. 8 shows processes following those of FIG. 7;

FIG. 9 shows processes following those of FIG. 8;

FIG. 10 is a plane view of a first intermediate manufactured object obtained in the course of the microstructure manufacturing method of the first aspect;

FIG. 11 is a plane view of a second intermediate manufactured object obtained in the course of the microstructure manufacturing method of the first aspect;

FIG. 12 is a partial enlarged cross-sectional view along line XII-XII in FIG. 11;

FIG. 13 is a partial enlarged cross-sectional view along line XIII-XIII in FIG. 11;

FIG. 14 is a partial enlarged cross-sectional view showing the same location as FIG. 12, after the cutting process;

FIG. 15 is a partial enlarged cross-sectional view showing the same location as FIG. 13, after the cutting process;

FIG. 16 shows a portion of the processes in the microstructure manufacturing method of a second aspect of the invention;

FIG. 17 shows processes following those of FIG. 16;

FIG. 18 shows processes following those of FIG. 17;

FIG. 19 shows processes following those of FIG. 18;

FIG. 20 is a plane view of a first intermediate manufactured object obtained in the course of the microstructure manufacturing method of the second aspect;

FIG. 21 is a plane view of a second intermediate manufactured object obtained in the course of the microstructure manufacturing method of the second aspect;

FIG. 22 is a partial enlarged cross-sectional view along line XXII-XXII in FIG. 21;

FIG. 23 is a partial enlarged cross-sectional view along line XXIII-XXIII in FIG. 21;

FIG. 24 is a partial enlarged cross-sectional view showing the same location as FIG. 22, after the cutting process;

FIG. 25 is a partial enlarged cross-sectional view showing the same location as FIG. 23, after the cutting process;

FIG. 26 is a plane view of a modified example of the microswitching device shown in FIG. 1;

FIG. 27 is a cross-sectional view along line XXVII-XXVII in FIG. 26;

FIG. 28 is a plane view of a first intermediate manufactured object obtained in the course of the microstructure manufacturing method of the modified example of the first aspect shown in FIG. 26;

FIG. 29 is a plane view of a second intermediate manufactured object obtained in the course of the microstructure manufacturing method of the modified example of the second aspect shown in FIG. 26;

FIG. 30 is a partial plane view of a microswitching device of the prior art, manufactured using MEMS technology;

FIG. 31 is a cross-sectional view along line XXXI-XXXI in FIG. 30;

FIG. 32 shows a portion of the manufacturing method of the microswitching device shown in FIG. 30;

FIG. 33 shows processes following those of FIG. 32; and

FIG. 34 shows a portion of the processes of another manufacturing method of the microswitching device shown in FIG. 30.

### DESCRIPTION OF THE PREFERRED EMBODIMENTS

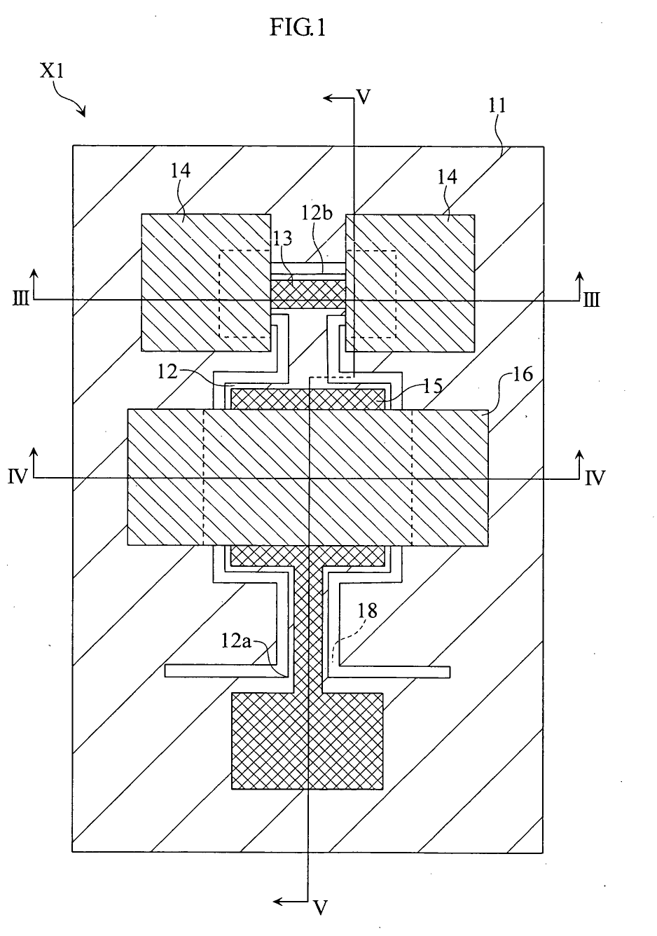

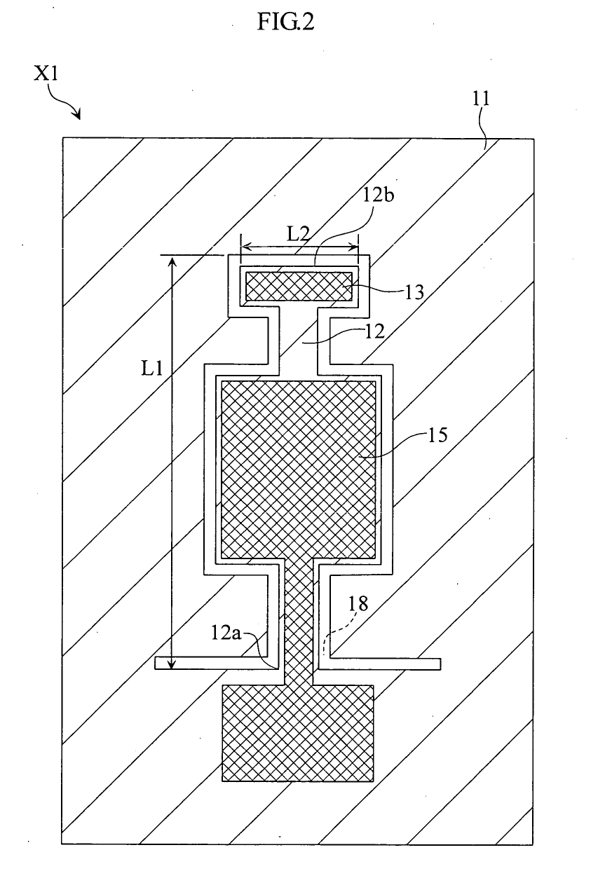

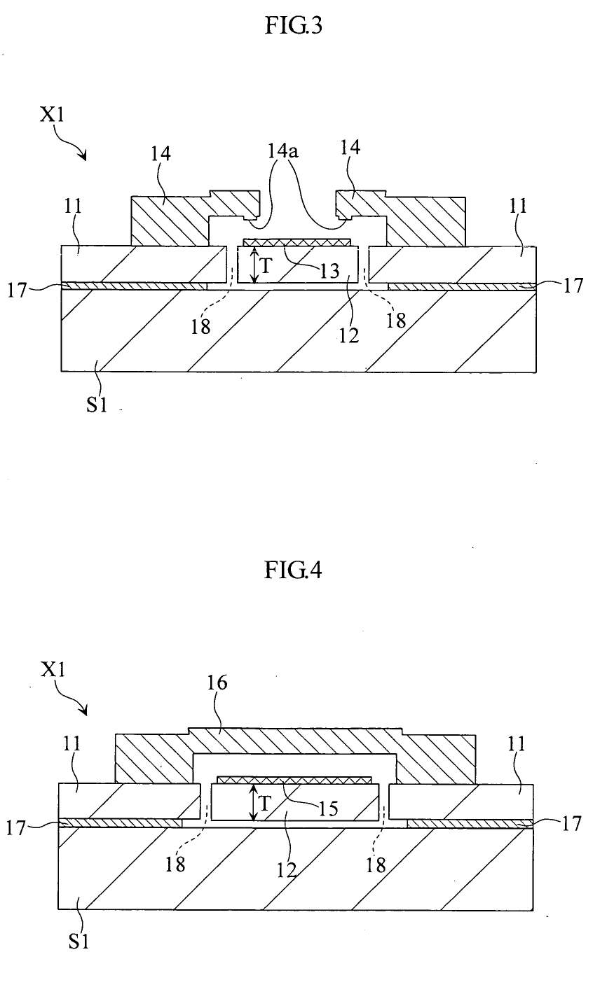

FIG. 1 to FIG. 5 show a microswitching device X1 which can be manufactured by a microstructure manufacturing method of this invention. FIG. 1 is a plane view of the microswitching device X1, and FIG. 2 is a partial plane view of the microswitching device X1. FIG. 3 to FIG. 5 are cross-sectional views along line III-III, line IV-IV, and line V-V in FIG. 1.

The microswitching device X1 comprises a base S1; fixed portion 11; movable portion 12; contact electrode 13; pair of contact electrodes 14 (omitted in FIG. 2); driving electrode 15; and driving electrode 16 (omitted in FIG. 2), and is configured as an electrostatic-driven device.

The fixed portion 11 is the first structural portion in the invention, and as shown in FIG. 3 to FIG. 5 is joined to the base S1 with a boundary layer 17 intervening. The fixed portion 11 and base S1 comprise single-crystal silicon or another silicon material. It is preferable that the silicon material forming the fixed portion 11 have a resistivity of 1000 Ω-cm or greater (i.e., no smaller than 1000 Ω-cm). The boundary layer 17 comprises, for example, silicon dioxide.

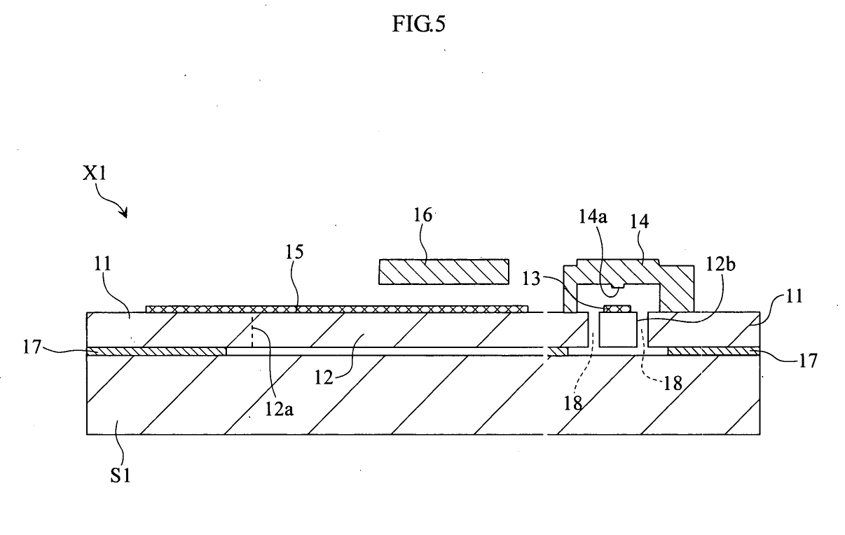

The movable portion 12 is the second structural portion of the invention, and as for example shown in FIG. 1, FIG. 2, or FIG. 5, has a fixed end 12a fixed to the fixed portion 11 and a free end 12b, extends opposing the base S1, and is surrounded by the fixed portion 11 with a slit 18 intervening. The length L1 of the movable portion 12 shown in FIG. 2 is for example 700 to 1000 μm, the length L2 is for example 100 to 200 μm, and the thickness T shown in FIG. 3 and FIG. 4 is for example 5 to 20 μm. The width of the slit 18 is for example 1.5 to 2.5 μm. It is preferable that the movable portion 12 comprise single-crystal silicon. When the movable portion 12 comprises single-crystal silicon, improper internal stresses do not occur in the movable portion 12 itself.

The contact electrode 13 is provided close to the free end 12b on the movable portion 12, as shown in FIG. 2. The contact electrode 13 comprises a prescribed conductive material.

As shown in FIG. 3 and FIG. 5, each of the pair of contact electrodes 14 is provided standing upright on the fixed portion 11, and moreover has a contact portion 14a opposing the contact electrode 13. Each of the contact electrodes 14 is connected to a prescribed circuit for switching via prescribed wiring (not shown). The contact electrodes 14 comprise a prescribed conductive material.

The driving electrode 15 is provided extending over the movable portion 12 and fixed portion 11, as shown in FIG. 2. The driving electrode 15 comprises a prescribed conductive material.

As shown in FIG. 4, the driving electrode 16 is provided standing upright such that both ends are joined to the fixed portion 11 and so as to span the driving electrode 15. The driving electrode 16 is connected to ground via prescribed wiring (not shown). The driving electrode 16 comprises a prescribed conductive material.

When a prescribed potential is applied to the driving electrode 15 of a microswitching device X1 configured in this way, an electrostatic attractive force arises between the driving electrodes 15 and 16. As a result, the movable portion 12 is elastically deformed to the position at which the contact electrode 13 comes into contact with the pair of contact electrodes 14 or with the contact portions 14a. In this way, the closed state of the microswitching device X1 is achieved. In the closed state, the pair of contact electrodes 14 is electrically bridged by the contact electrode 13, and current is allowed to flow between the pair of contact electrodes 14. In this way, for example, a high-frequency signal turn-on state can be achieved.

By halting the application of a potential to the driving electrode 15 of the microswitching device X1 in the closed state, the electrostatic attractive force acting movable portion 12 returns to its natural state, and the contact electrode 13 is isolated from the contact electrodes 14. In this way, as the open state of the microswitching device X1, such as shown in FIG. 3 and FIG. 5, is achieved. In the open state, the pair of contact electrodes 14 is electrically separated, and current is prevented from flowing between the pair of contact electrodes 14. In this way, for example, a high-frequency signal turn-off state can be achieved.

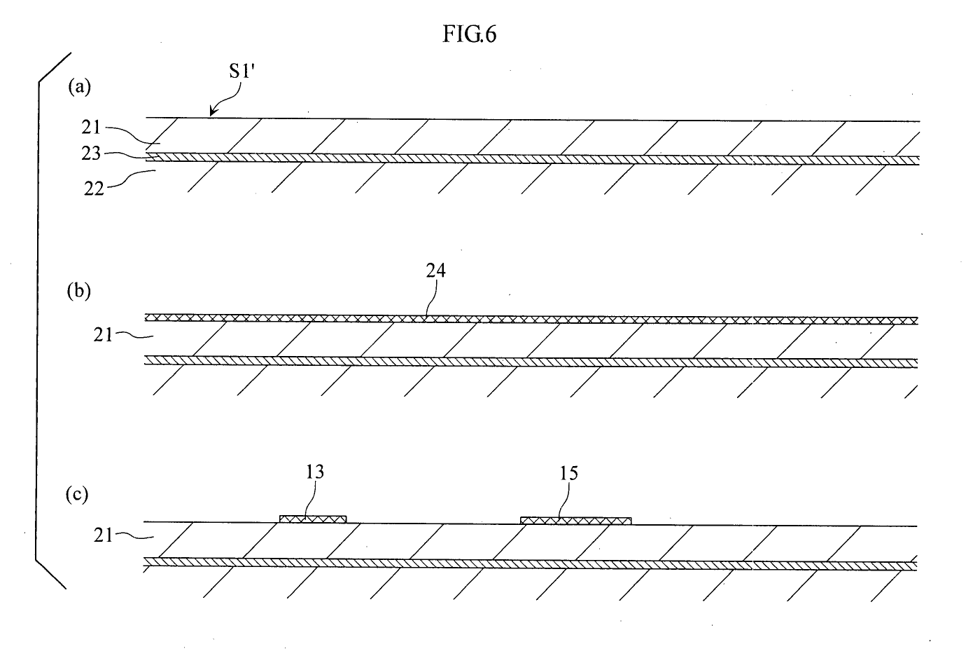

FIG. 6 to FIG. 9 show the microstructure manufacturing method of the first aspect of the invention. This method is a method for manufacturing the above-described microswitching device X1. In FIG. 6 to FIG. 9, changes in the cross-section at a plurality of locations during processes to manufacture the microswitching device X1 are shown as changes in a single cross section. This single cross-section is a continuous cross-section which models the cross-sections at a plurality of prescribed locations comprised by a single microswitching device formation region of the material substrate being processed.

In this method, first a material substrate S1′, shown in FIG. 6(a), is prepared. The material substrate S1′ is an SOI (Silicon On Insulator) substrate, having a stacked structure comprising a first layer 21, second layer 22, and intermediate layer 23 therebetween. It is preferable that the thickness of the first layer 21 be 3 μm or greater, and is for example 5 to 20 μm; the thickness of the second layer 22 is for example 400 to 600 μm; and the thickness of the intermediate layer 23 is for example from 2 to 4 μm. The first layer 21 comprises for example single-crystal silicon, and is processed to form the above-described fixed portion 11 and movable portion 12. The second layer 22 comprises for example single-crystal silicon, and is processed to form the above-described base S1. The intermediate layer 23 comprises for example silicon dioxide, and is processed to form the above-described boundary layer 17.

Next, as shown in FIG. 6(b), the conductive film 24 is formed on the first layer 21. The conductive film 24 comprises a material having resistance to the reactive ion etching (RIE) used in the subsequent cutting process. One such material is for example Au. More specifically, in this process, a sputtering method is used to deposit for example Cr on the first layer 21, following which Au for example is deposited thereupon. The thickness of the Cr film is for example 50 nm, and the thickness of the Au film is for example 500 nm.

Next, as shown in FIG. 6(c), patterning is used to form the contact electrode 13 and driving electrode 15 from the conductive film 24. Specifically, after using a photolithography method to form a prescribed resist pattern on the conductive film 24, the resist pattern is used as a mask to perform etching of the conductive film 24.

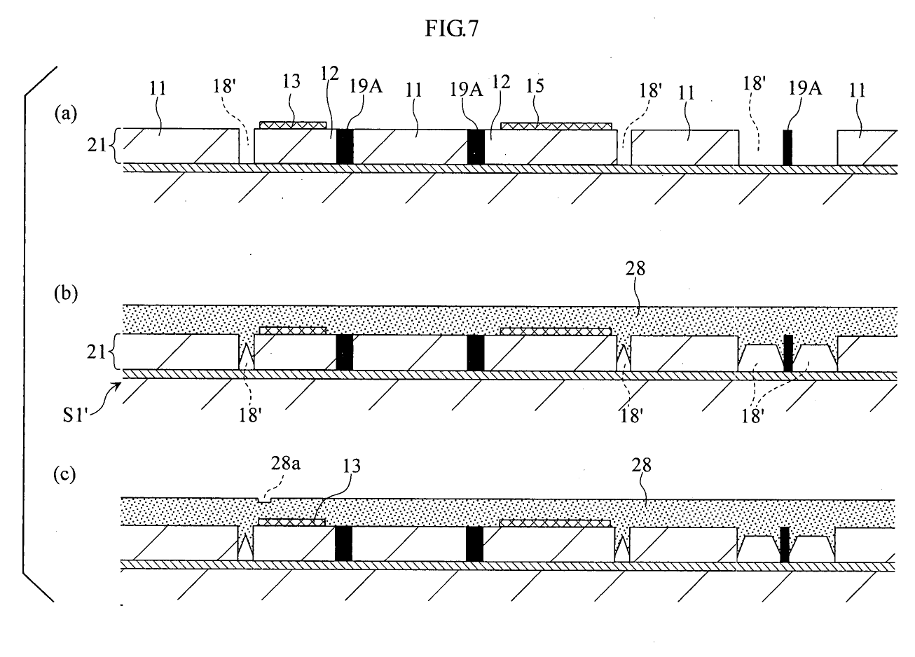

Next, as shown in FIG. 7(a), a slit 18′ is formed by etching of the first layer 21. Specifically, after using a photolithography method to form a prescribed resist pattern on the first layer 21, the resist pattern is used as a mask to perform etching of the first layer 21. As the etching technique, RIE, which is an anisotropic etching method, is performed using SF₆ gas as the etching gas.

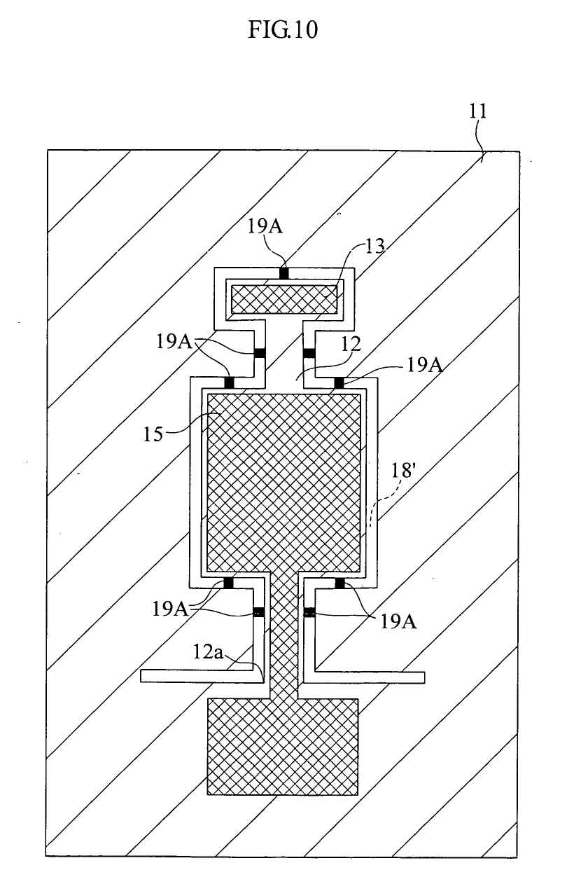

In this process, the fixed portion 11, movable portion 12, and the support beams 19A bridging these are formed (this process is equivalent to the formation process of the invention). Specifically, as shown in FIG. 10, the fixed portion 11, movable portion 12, and support beams 19A bridging these are formed by patterning (FIG. 10 is a plane view of a first intermediate manufactured object obtained in this process). For purposes of clarification, in the figure the support beams 19A are filled with black. In FIG. 7(a), the cross-sectional face of the support beam 19A on the rightmost end is shown; the cross-sectional faces of the other support beams 19A in the direction of extension are shown. It is preferable that the widths of the support beams 19A (the length in the horizontal direction of the rightmost support beam 19A in FIG. 7(a)) be 0.3 to 2 μm.

Next, as shown in FIG. 7(b), a sacrificial layer 28 is formed on the side of the first layer 21 of the material substrate S1′ so as to fill the slit 18′. As the material of the sacrificial layer, for example, silicon dioxide can be used. As the technique for forming the sacrificial layer 28, for example, plasma CVD or sputtering can be used.

Next, as shown in FIG. 7(c), a depression 28a is formed in the sacrificial layer 28 at the location corresponding to the contact electrode 13. Specifically, after using photolithography to form a prescribed resist pattern on the sacrificial layer 28, the resist pattern is used as a mask to etch the sacrificial layer 28. As the etching method, wet etching can be used. As the etching liquid used in wet etching, for example, buffered hydrofluoric acid (BHF) can be used. BHF can also be used in subsequent wet etching of the sacrificial layer 28. The depression 28a is used to form the contact portion 14a of the contact electrode 14, and has a depth of for example 1 μm.

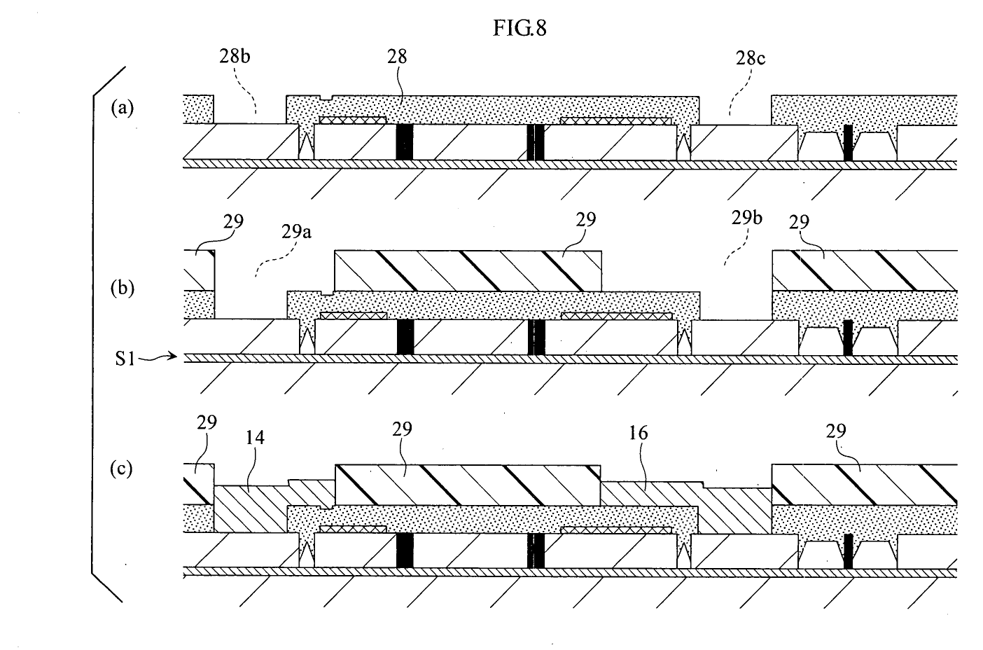

Next, as shown in FIG. 8(a), the sacrificial layer 28 is patterned to form the opening portions 28b and 28c. Specifically, after using photolithography to form a prescribed resist pattern on the sacrificial layer 28, the resist pattern is used as a mask to perform etching of the sacrificial layer 28. As the etching method, wet etching can be used. The opening portion 28b is used to expose the area of the fixed portion 11 to which the contact electrode 14 is joined. The opening portion 28c is used to expose the area of the fixed portion 11 to which the driving electrode 16 is joined.

Next, after forming an underlayer (not shown) for conduction on the surface of the material substrate 11 on the side on which the sacrificial layer 28 is provided, a resist pattern 29 is formed, as shown in FIG. 8(b). The underlayer can for example be formed by depositing Cr to a thickness of 50 nm by sputtering, followed by deposition of Au thereupon to a thickness of 500 nm. The resist pattern 29 has an opening portion 29a corresponding to the contact electrode 14 and an opening portion 29b corresponding to the driving electrode 16.

Next, as shown in FIG. 8(c), the contact electrodes 14 and driving electrode 16 are formed. The contact electrodes 14 and driving electrode 16 comprise material having resistance to RIE, used in the subsequent cutting process. Specifically, in this process electroplating is used to grow gold, for example, on the underlayer exposed at the opening portions 28b, 28c, 29a and 29b.

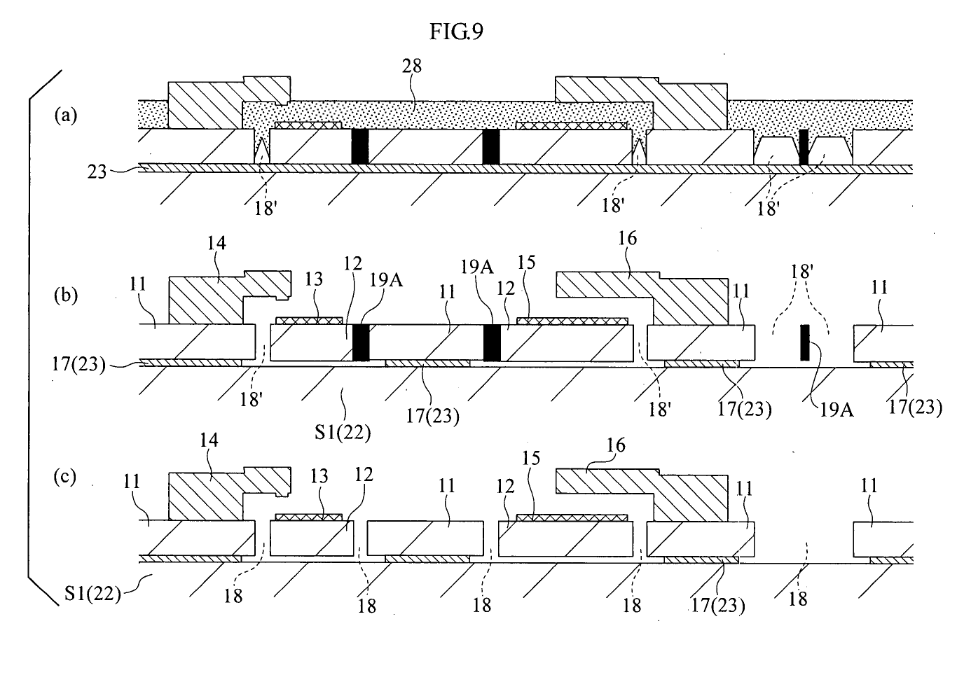

Next, as shown in FIG. 9(a), the resist pattern 29 is removed by etching. Then, the portion of the above-described exposed underlayer used in electroplating is removed by etching. In these processes of removal by etching, wet etching can be used.

Next, as shown in FIG. 9(b), the sacrificial layer 28 and a portion of the intermediate layer 23 are removed. Specifically, the sacrificial layer 28 and intermediate layer 23 are subjected to wet etching (wet etching process). In this etching treatment, first the sacrificial layer 28 is removed, and then a portion of the intermediate layer 23 is removed from the location bordering the slit 18′. This etching is halted after an appropriate gap is formed between the entirety of the movable portion 12 and the second layer 22. In this way, the boundary layer 17 is formed remaining in the intermediate layer 23. The second layer 22 forms the base S1.

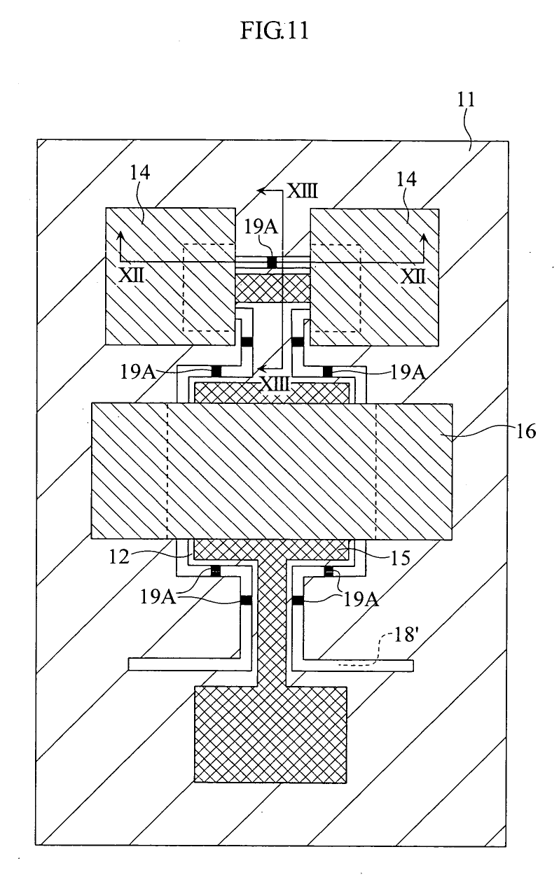

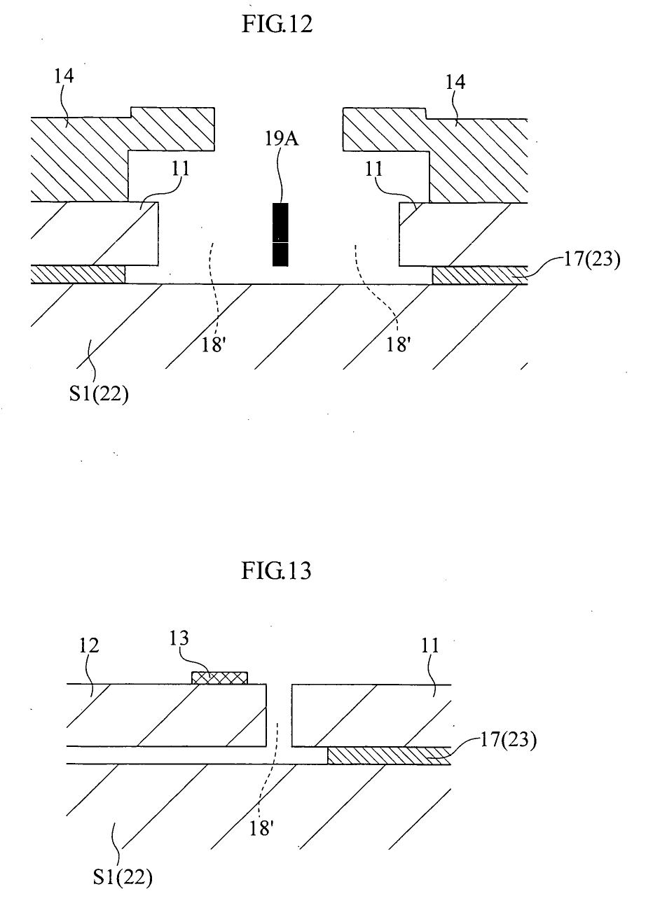

FIG. 11 is a plane view of a second intermediate manufactured object obtained through this wet etching process. FIG. 12 and FIG. 13 are partial enlarged cross-sectional views along line XII-XII and line XIII-XIII in FIG. 11, respectively. As shown in FIG. 12 for the vicinity of one support beam 19A, in the etching of this process, regions of the sacrificial layer 28 existing between the second layer 22 and each of the support beams 19A, which are even smaller than the movable portion 12, are also removed by etching. As can be understood by referring to FIG. 10 as well as to FIG. 11, each of the support beams 19A is formed in a position which does not oppose the contact electrodes 14 or driving electrode 16.

Next, after removing as necessary, by another wet etching process, a portion of the underlayer (for example, a Cr film) adhering to the lower surfaces of the contact electrodes 14 and driving electrode 16, drying is performed. Specifically, the etching liquid adhering to the device surface is replaced with a first rising liquid, which is water or similar, the first rinsing liquid is replaced with a second rinsing liquid, which is alcohol or similar, and then the second rinsing liquid is caused to evaporate, using blowing of nitrogen gas or another method.

Next, as shown in FIG. 9(c), RIE is used to cut or remove the support beams 19A (cutting process). In this process, RIE is performed using for example SF₆ gas as the etching gas, without providing a protective film to protect the contact electrodes 13 and 14 or driving electrodes 15 and 16. Because the contact electrodes 13 and 14 and driving electrodes 15 and 16 comprise materials having resistance to the RIE of this process, as explained above, no improper erosion occurs in this process even without a protective film. The above-described Au used as a component material of the contact electrodes 13 and 14 and driving electrodes 15 and 16 has sufficient resistance to SF₆ gas. In this process, the slit 18 is formed.

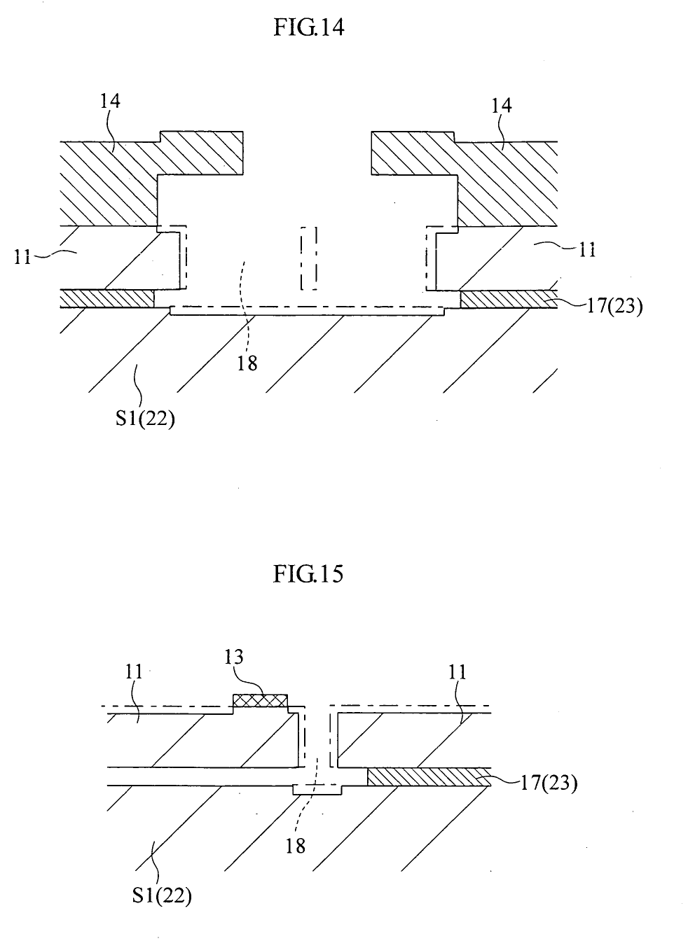

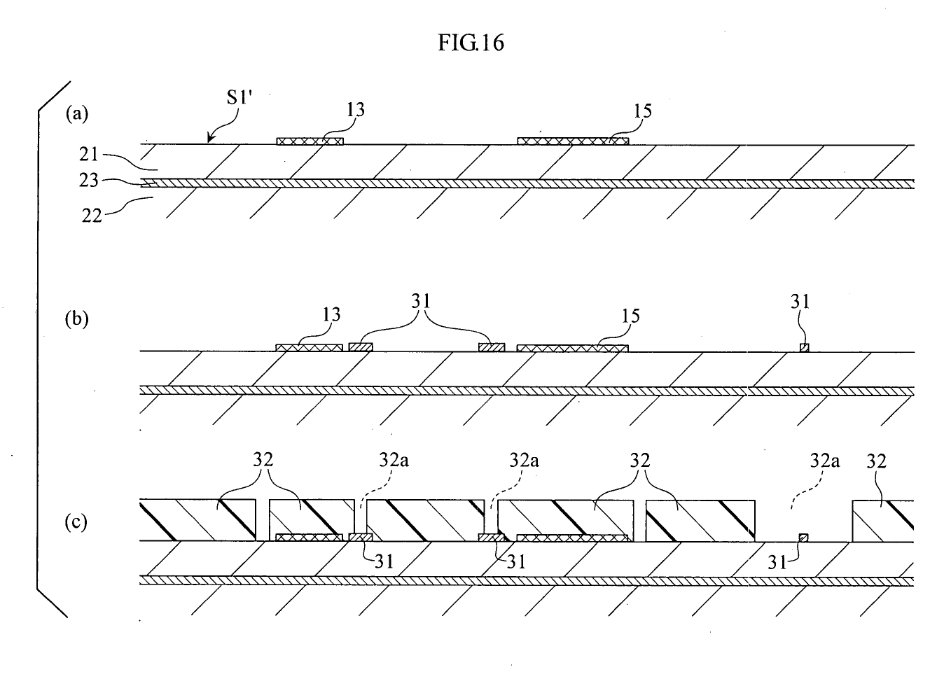

FIG. 14 and FIG. 15 are partial enlarged cross-sectional views of prescribed locations after this process. FIG. 14 shows the same location as in FIG. 12, and FIG. 15 shows the same location as in FIG. 13. As shown in FIG. 14 and FIG. 15, the vicinity of the slit 18 at the exposed surface of the fixed portion 11, the exposed surface of the movable portion 12, and the exposed surface of the base S1 is removed by the RIE of this process. In FIG. 14 and FIG. 15, the outline of each portion prior to removal is indicated by a dot-dash line.

Thus the microswitching device X1 shown in FIG. 1 to FIG. 5 can be manufactured as described above. In this method, with the fixed portion 11 joined to the base S1 and the movable portion 12 having a fixed end 12a fixed to the fixed portion 11 and opposing but not joined to the base S1 bridged by support beams 19A, the wet etching process described above referring to FIG. 9(b) and the subsequent drying process are performed. The support beams 19A bridging the fixed portion 11 and movable portion 12 are created in the first layer 21 of the base S1, similarly to the fixed portion 11 and movable portion 12, in the formation process described referring to FIG. 7(a). That is, the support beams 19A are integral and continuous with the fixed portion 11 and movable portion 12. High strength for bridging the fixed portion 11 and movable portion 12 can easily be realized in such support beams 19A. Consequently in the drying process, which adopts the alcohol drying method, the support beams 19A support the movable portion 12, and can prevent drawing of the movable portion 12 to the side of the base S1 and to the side of the contact electrodes 14 and driving electrode 16. Hence by means of this method, the microswitching device X1 can be manufactured while completely avoiding the sticking phenomenon.

In this method, it is preferable that the widths of the support beams 19A be 0.3 to 2 μm, as described above, and it is preferable that in the cutting process described above referring to FIG. 9(c), the fixed portion 11 and movable portion 12 have a thickness of 3 μm or greater, and that the thickness be for example 5 to 20 μm. This configuration is suitable for cutting by RIE of the support beams 19A while leaving the fixed portion 11 and movable portion 12 in the cutting process.

In addition, in this method, plating can be used to form thick contact electrodes 14 opposing the contact electrode 13, and having contact portions 14a, on the sacrificial layer 28. Hence the thickness of the pair of contact electrodes 14 can be set so as to obtain a desired resistance value. Thick contact electrodes 14 are preferable in order to reduce the insertion loss of the microswitching device X1.

FIG. 16 to FIG. 19 show a portion of the processes of a method of manufacture of microstructures in a second aspect of the invention. This method is another method of manufacturing the above-described microswitching device XI. In FIG. 16 to FIG. 19, changes in the cross-sections of a plurality of locations during the manufacturing process of the microswitching device X1 are shown as changes in a single cross-section. This single cross-section is a continuous cross-section which models the cross-sections at a plurality of prescribed locations comprised by a single microswitching device formation region of the material substrate being processed.

In this method, first a contact electrode 13 and driving electrode 15 are formed on the first layer 21 of the material substrate S1′, as shown in FIG. 16(a). The specific method used is similar to that described above in the first aspect referring to FIGS. 6(a) to 6(c).

Next, as shown in FIG. 16(b), an etching amount adjustment films 31 are formed on the first layer 21. Each etching amount adjustment film 31 is positioned corresponding to the planned location of a support beam on the first layer 21, and comprises silicon oxide or silicon nitride. The thickness of the etching amount adjustment films 31 is for example 30 to 50 nm.

Next, as shown in FIG. 16(c), a photolithography method is used to form a resist pattern 32 on the first layer 21. The resist pattern 32 has an opening portion 32a corresponding to the slit 18. An etching amount adjustment film 31 partially borders the opening portion 32a.

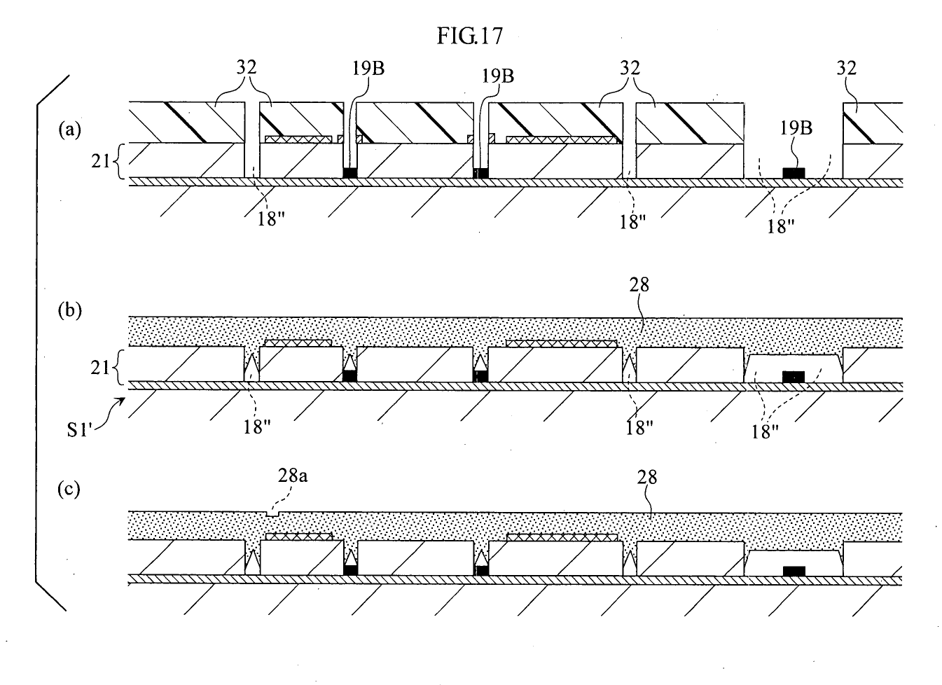

Next, as shown in FIG. 17(a), the resist pattern 32 is used as a mask to perform etching of the first layer 21, in order to form the slit 18′. As the etching method, RIE using SF₆ gas as the etching gas can be employed.

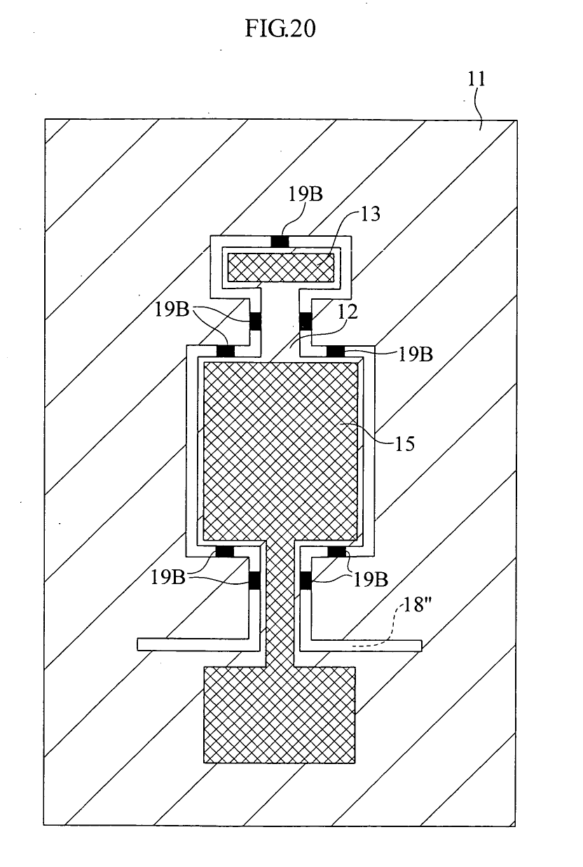

In this process, the fixed portion 11, movable portion 12, and support beams 19B bridging these are formed (this process is the formation process in the invention). Specifically, as shown in FIG. 20, the fixed portion 11, movable portion 12, and support beams 19B bridging these are formed by patterning (FIG. 20 is a plane view of a first intermediate manufactured object obtained in this process). For purposes of clarification, in the figure the support beams 19B are filled with black. In FIG. 17(a), the cross-sectional face of the support beam 19B on the rightmost end is shown; the cross-sectional faces of the other support beams 19B in the direction of extension are shown. It is preferable that the thicknesses of the support beams 19B be 1 to 3 μm and the widths thereof (the length in the horizontal direction of the rightmost support beam 19B in FIG. 17(a)) be 10 to 50 μm.

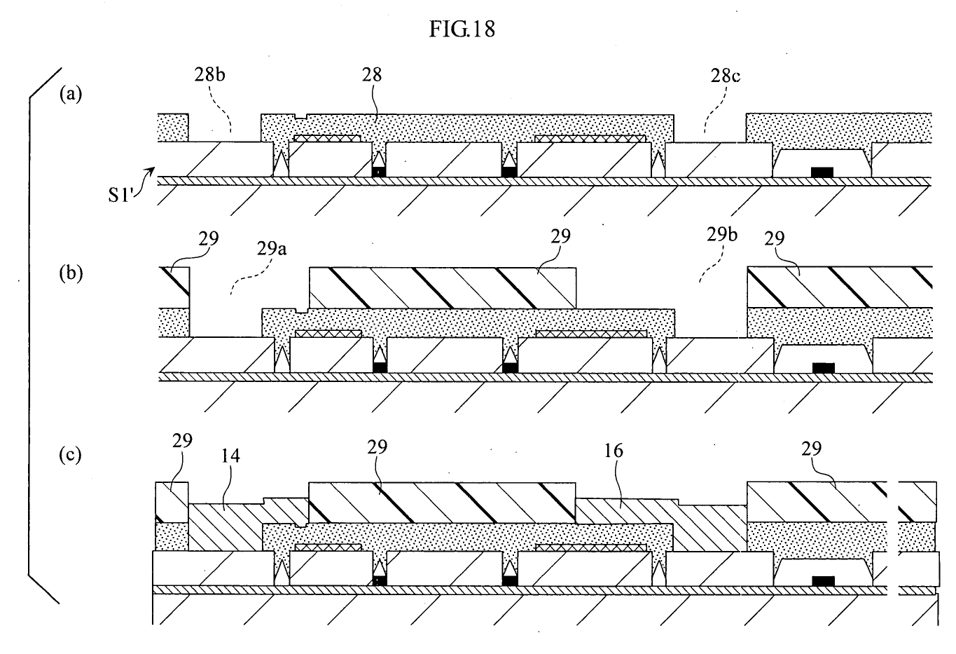

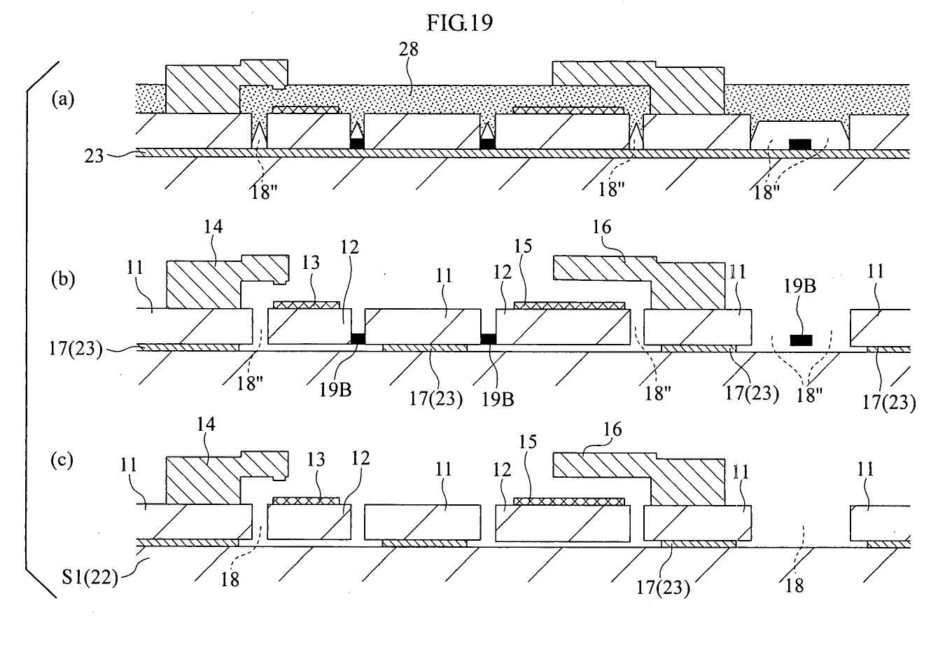

Next, as shown in FIG. 17(b), a sacrificial layer 28 is formed on the side of the first layer 21 of the material substrate S1′. Then, as shown in FIG. 17(c), a depression 28a is formed at the location corresponding to the contact electrode 13 in the sacrificial layer 28. Next, as shown in FIG. 18(a), the sacrificial layer 28 is patterned to form opening portions 28b and 28c. Then, after forming an underlayer (not shown) to pass a current on the surface of the material substrate S1′ on the side on which the sacrificial layer 28 is provided, a resist pattern 29 is formed, as shown in FIG. 18(b). The resist pattern 29 has opening portions 29a corresponding to the contact electrodes 14 and an opening portion 29b corresponding to the driving electrode 16. Next, as shown in FIG. 18(c), the contact electrodes 14 and the driving electrode 16 are formed. Then, as shown in FIG. 19(a), the resist pattern 29 is removed by etching. Thereafter, the exposed portion of the above-described underlayer for use in electroplating is removed by etching. The details of these processes are similar to those described above in the first aspect, referring to FIG. 7(b) to FIG. 9(a).

Next in this method, the sacrificial layer 28 and a portion of the intermediate layer 23 are removed, as shown in FIG. 19(b). Specifically, wet etching of the sacrificial layer 28 and intermediate layer 23 is performed (wet etching process). In this etching treatment, first the sacrificial layer 28 is removed, and then a portion of the intermediate layer 23 is removed from the location bordering the slit 18″. This etching is halted after an appropriate gap is formed between the entirety of the movable portion 12 and the second layer 22. In this way, a boundary layer 17 is formed to remain in the intermediate layer 23. The second layer 22 forms the base S1.

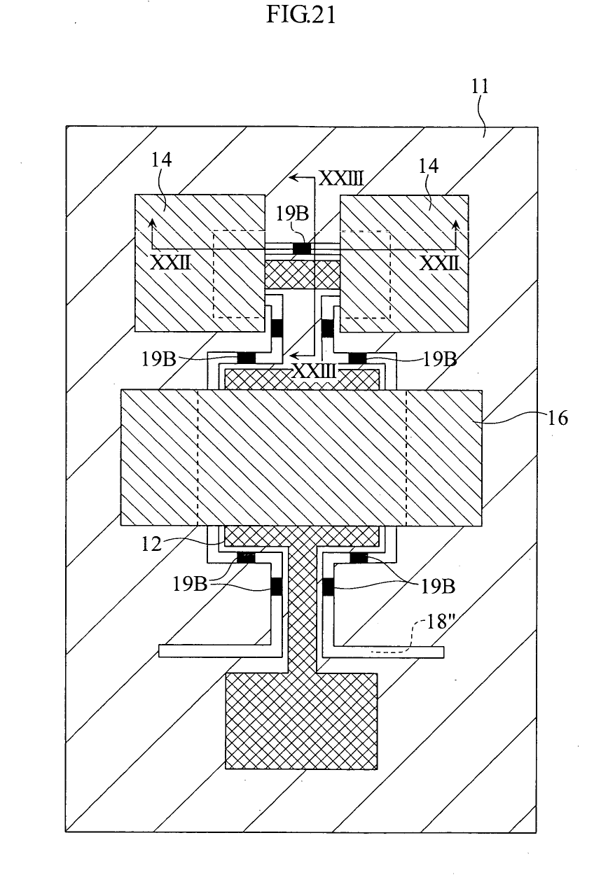

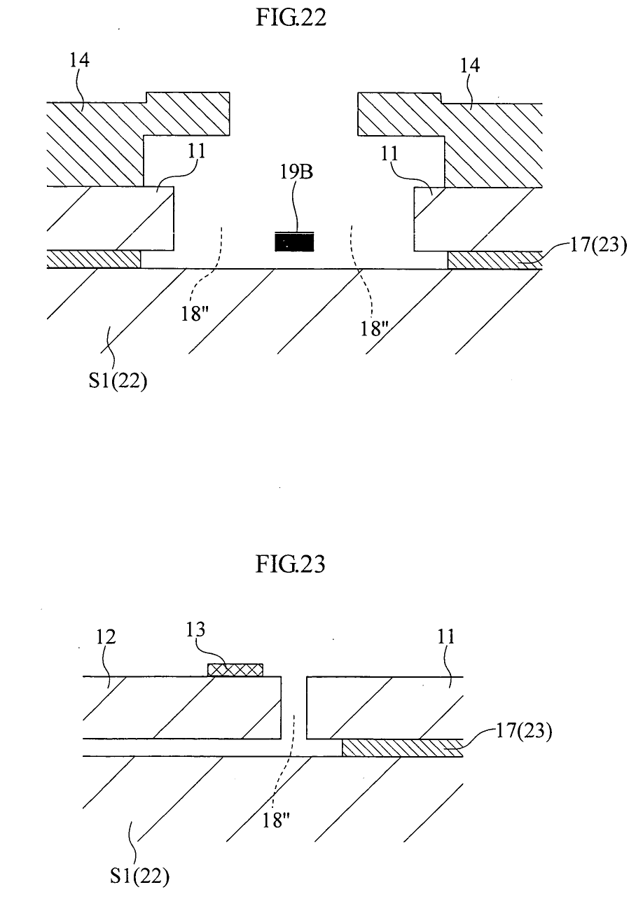

FIG. 21 is a plane view of a second intermediate manufactured object obtained in this process. FIG. 22 and FIG. 23 are partial enlarged cross-sectional views along line XXII-XXII and line XXIII-XXIII respectively in FIG. 21. As shown in FIG. 22 for the vicinity of one support beam 19B, in the etching of this process the regions of the sacrificial layer 28 intervening between each of the support beams 19B, which are even smaller than the movable portion 12, and the second layer 22 are removed by etching. As can be understood from FIG. 20 in addition to FIG. 21, each of the support beams 19B is formed in a position which does not oppose the contact electrodes 14 or driving electrode 16.

Next, after using wet etching to remove as necessary a portion of the underlayer (for example a Cr film) adhering to the lower surfaces of the contact electrodes 14 and driving electrodes 16, drying is performed. Specifically, the etching liquid adhering to the device surface is replaced with a first rinsing liquid, the first rinsing liquid is replaced with alcohol or another second rinsing liquid, and blowing of nitrogen gas or other means is used to cause evaporation of the second rinsing liquid.

Next, as shown in FIG. 19(c), RIE is used to cut or remove the support beams 19B (cutting process). In this process, RIE is performed using for example SF₆ gas as the etching gas, without providing a protective film to protect the contact electrodes 13 and 14 or driving electrodes 15 and 16. Because the contact electrodes 13 and 14 and driving electrodes 15 and 16 comprise materials having resistance to the RIE of this process, as explained above, no improper erosion occurs in this process even without a protective film. In this process, the slit 18 is formed.

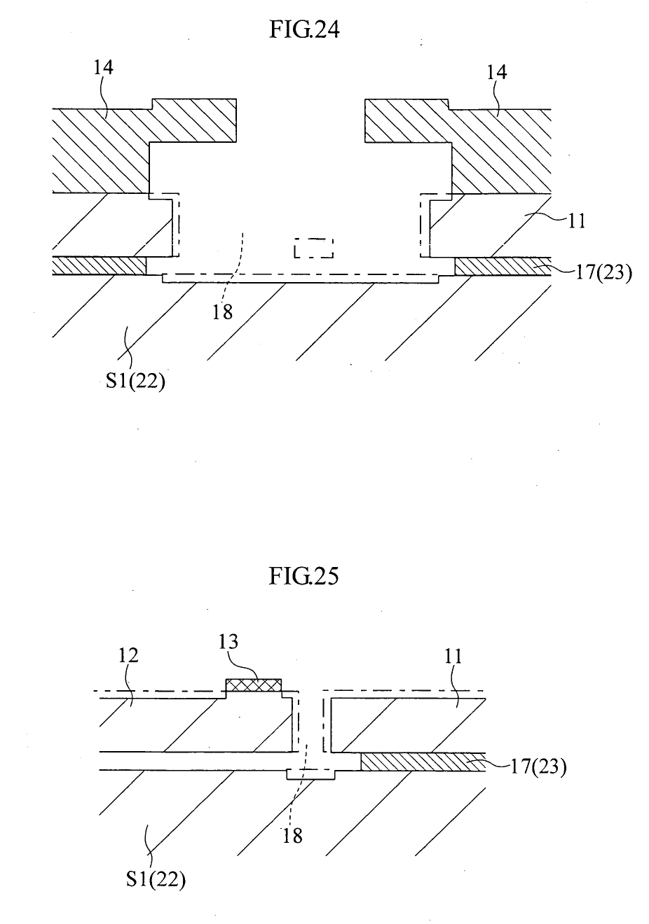

FIG. 24 and FIG. 25 are partial enlarged cross-sectional views of prescribed locations after this process. FIG. 24 shows the same location as in FIG. 22, and FIG. 25 shows the same location as in FIG. 23. As shown in FIG. 24 and FIG. 25, the vicinity of the slit 18 at the exposed surface of the fixed portion 11, the exposed surface of the movable portion 12, and the exposed surface of the base S1 is removed by the RIE of this process. In FIG. 24 and FIG. 25, the outline of each portion prior to removal is indicated by a dot-dash line.

In this way, the microswitching device X1 shown in FIG. 1 to FIG. 5 can be manufactured. In this method, with the fixed portion 11 joined to the base S1 and the movable portion 12 opposed to the base S1 without being joined thereto and having a fixed end 12a fixed to the fixed portion 11 being bridged by support beams 19B, the wet etching process described above referring to FIG. 19(b) and the subsequent drying process are performed. The support beams 19B which bridge the fixed portion 11 and movable portion 12 are created in the first layer 21 of the material substrate S1, similarly to the fixed portion 11 and movable portion 12, in the formation process described above referring to FIG. 17(a). That is, the support beams 19B are integral and continuous with the fixed portion 11 and movable portion 12. High strength for bridging the fixed portion 11 and movable portion 12 can easily be realized in such support beams 19B. Consequently in the drying process, which adopts the alcohol drying method, the support beams 19B support the movable portion 12, and can prevent drawing of the movable portion 12 to the side of the base S1 and to the side of the contact electrodes 14 and driving electrode 16. Hence by means of this method, the microswitching device X1 can be manufactured while completely avoiding the sticking phenomenon.

In this method, it is preferable that the support beams 19B be of thickness 1 to 3 μm as described above, and in the cutting process described above referring to FIG. 19(c), it is preferable that the fixed portion 11 and movable portion 12 be of thickness 3 μm or above, and have a thickness of for example 5 to 20 μm. Such a configuration is suitable for cutting the support beams 19B by RIE, while leaving the fixed portion 11 and movable portion 12.

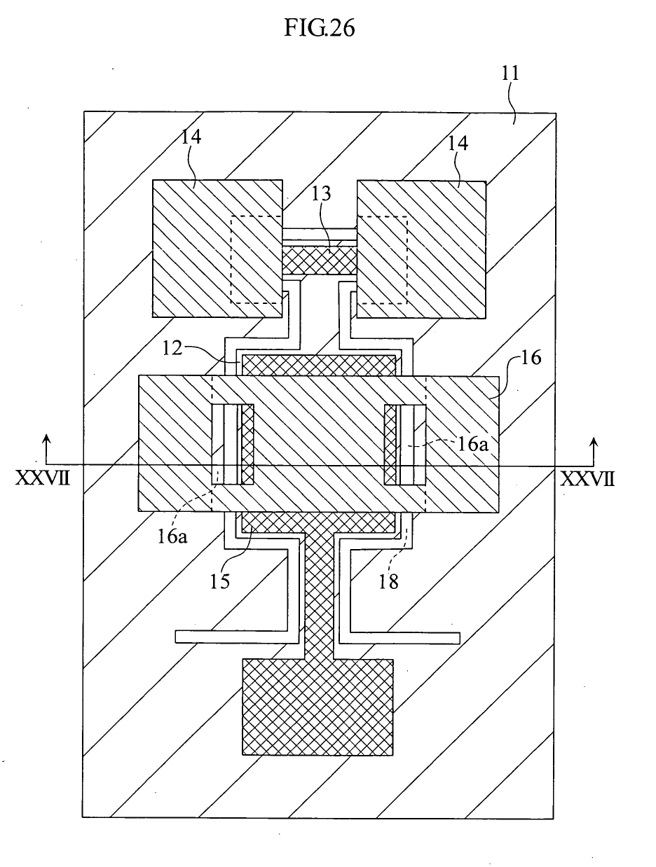

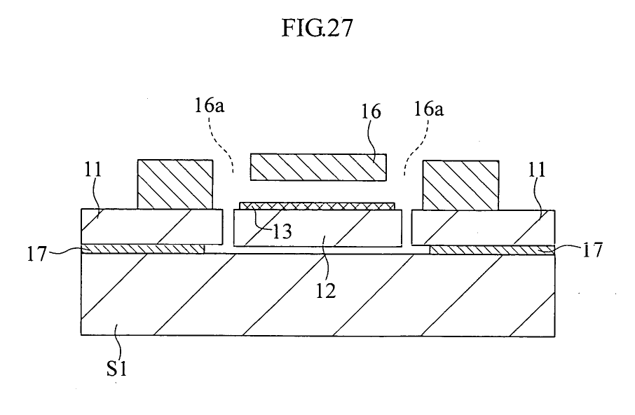

FIG. 26 and FIG. 27 show a modified example of the microswitching device X1. FIG. 26 is a plane view of the modified example, and FIG. 27 is a cross-sectional view along line XXVII-XXVII in FIG. 26.

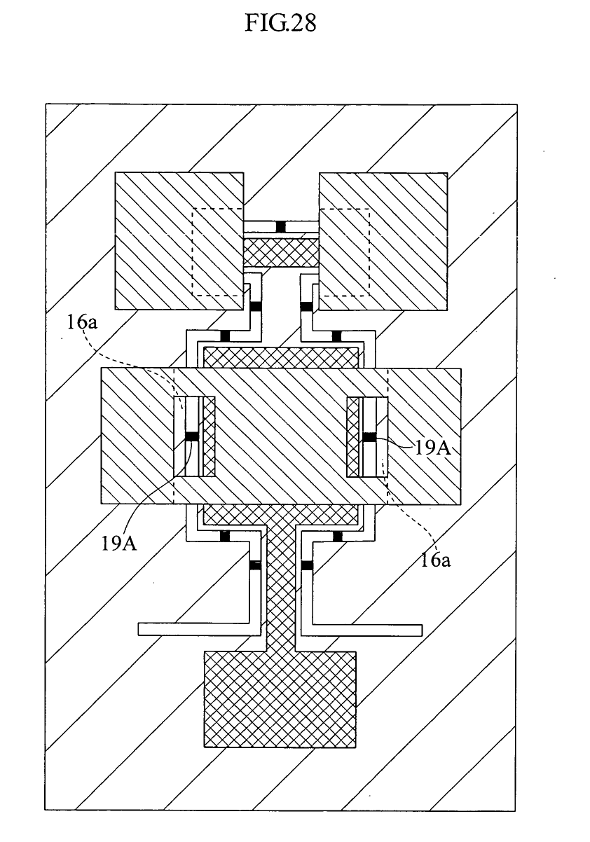

In this modified example, the driving electrode 16 has an opening portion 16a in a location corresponding to the slit 18. When manufacturing the device of this modified example using the microstructure manufacturing method of the first aspect, supplementary support beams 19A can be formed at positions opposing the opening portions 16a in the formation process described above referring to FIG. 7(a), and in the cutting process described above referring to FIG. 9(c), the supplementary support beams 19A bordering the opening portions 16a can be cut by RIE, as shown in FIG. 28.

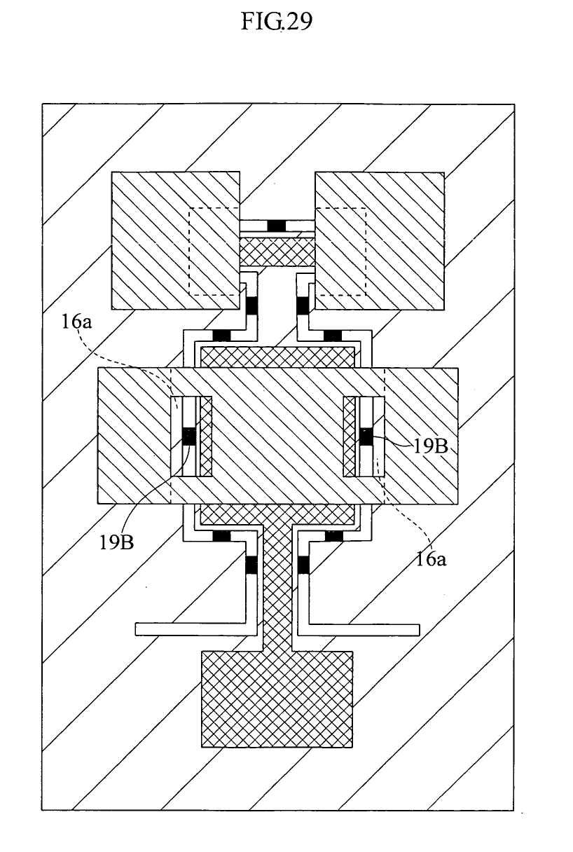

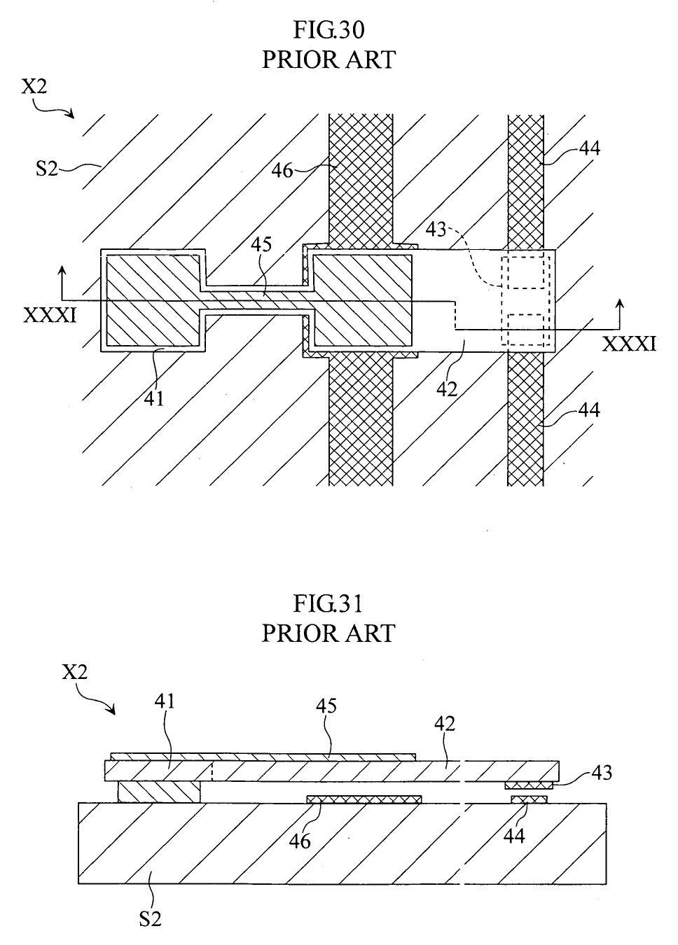

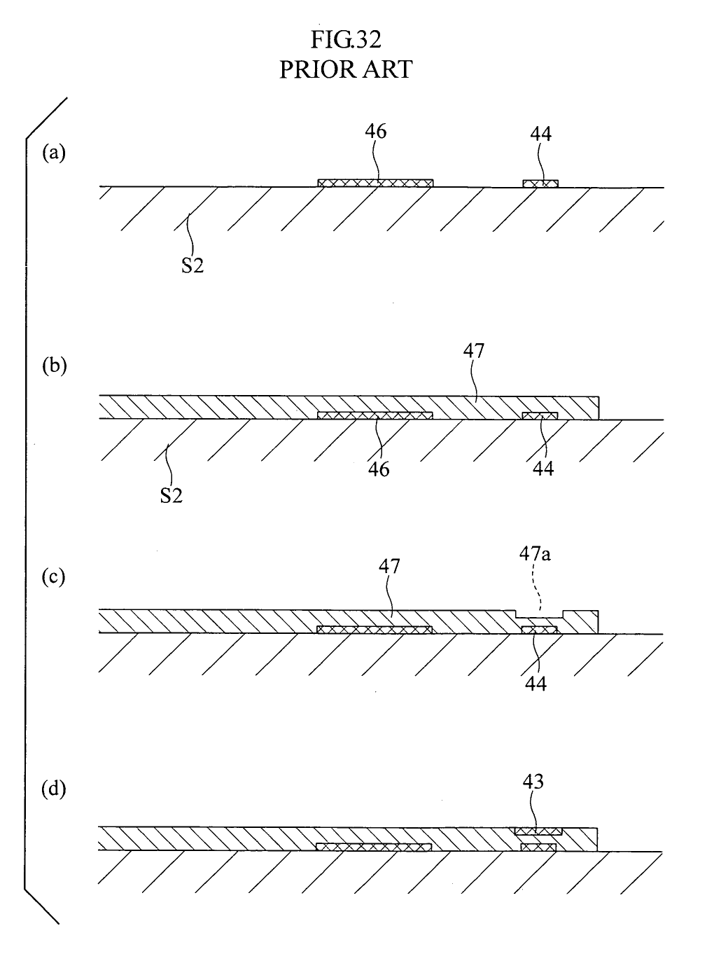

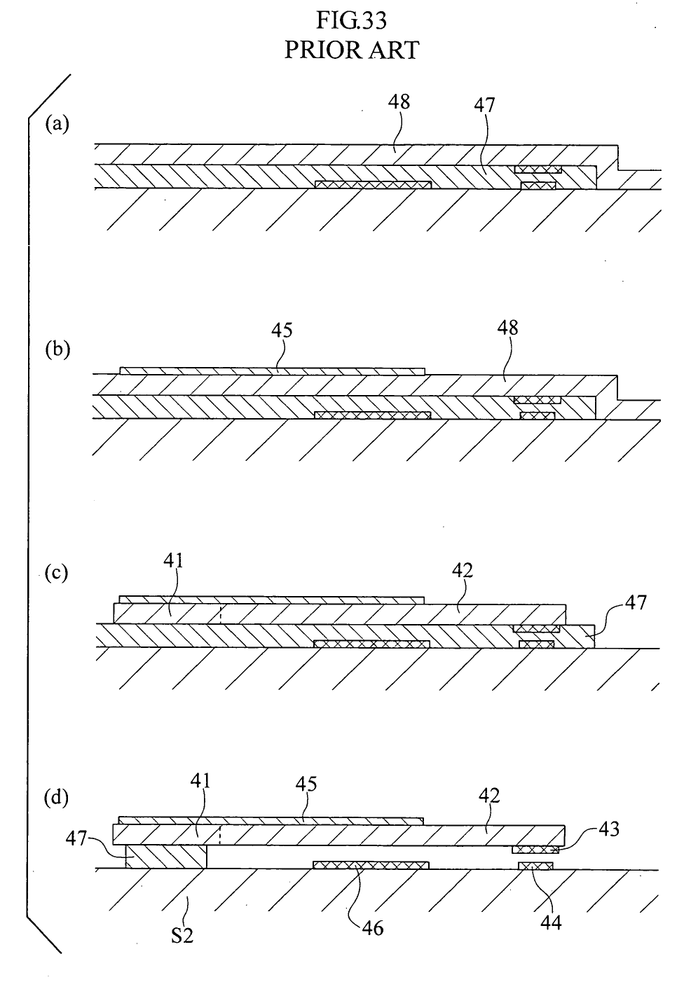

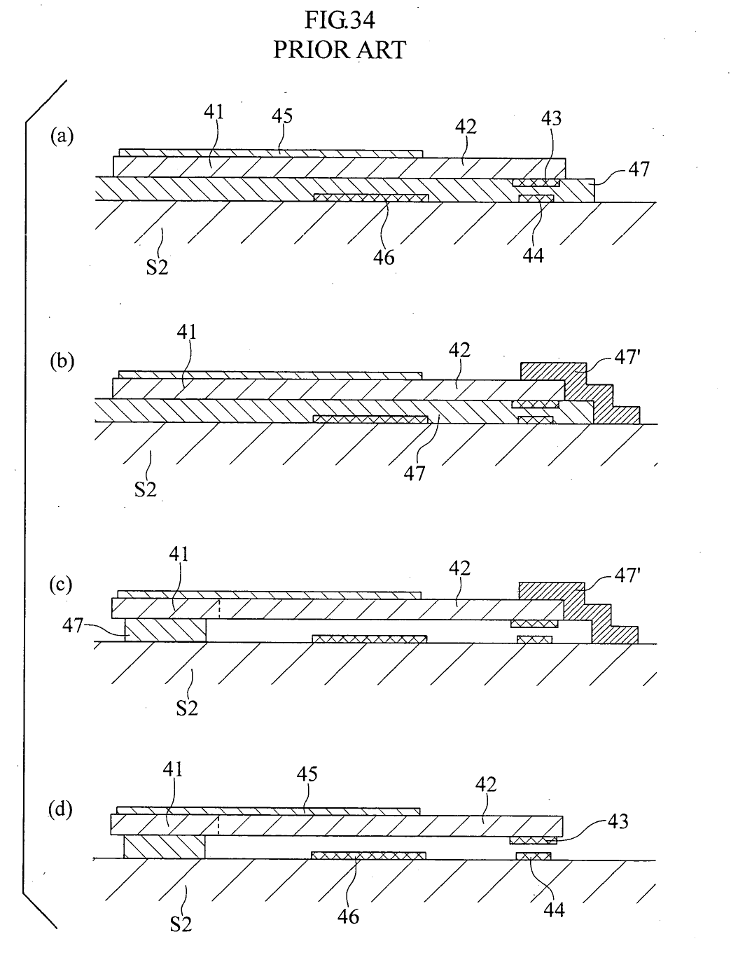

On the other hand, when the microswitching device of the modified example is manufactured using the microstructure manufacturing method of the second aspect, in the formation process described above referring to FIG. 17(a), supplementary support beams 19B can be formed at positions opposing the opening portions 16a, and in the cutting process described above referring to FIG. 19(c), the supplementary support beams 19B bordering the opening portions 16a can be cut by RIE, as shown in FIG. 29.

In this way, by means of a configuration in which the driving electrode 16 has opening portions 16a at locations corresponding to the slit 18, numerous support beams 19A or support beams 19B can be utilized. An increased number of support beams 19A or support beams 19B is suitable for realizing high strength for bridging the fixed portion 11 and movable portion 12 with the support beams 19A or 19B.

1. A microstructure manufacturing method for manufacturing a microstructure comprising a base, a first structural portion joined to the base, and a second structural portion having a fixed end fixed to the first structural portion and which is opposed to the base, by performing processing of a material substrate having a stacked structure, comprising a first layer, a second layer, and an intermediate layer between the first layer and second layer; the microstructure manufacturing method comprising:
a formation step of forming, in the first layer, the first structural portion, the second structural portion having a fixed end fixed at the first structural portion, and a support beam bridging the first and second structural portions;
a wet etching step of removing, by wet etching, a region of the intermediate layer between the second layer and the second structural portion;
a drying step; and
a cutting step of cutting the support beam.

2. A microstructure manufacturing method for manufacturing a microstructure comprising a base, a first structural portion joined to the base, a second structural portion having a fixed end fixed to the first structural portion and which is opposed to the base, a first electrode provided on the side of the second structural portion opposite the base, and a second electrode, having a region opposed to the first electrode, and which is joined to the first structural portion, by performing processing of a material substrate having a stacked structure, comprising a first layer, a second layer, and an intermediate layer between the first layer and second layer; the microstructure manufacturing method comprising:
a step of forming, in the first layer, the first electrode on a region to be processed to form the second structural portion;
a formation step of forming, in the first layer, the first structural portion, the second structural portion having a fixed end fixed at the first structural portion, and a support beam bridging the first and second structural portions;
a step of forming a sacrificial layer, having an opening portion to expose the second electrode joining area in the first structural portion and covering the side of the first layer;
a second electrode formation step of forming the second electrode, having a region opposing the first electrode with the sacrificial layer intervening, and joined to the first structural portion in the second electrode joining area;
a wet etching step of removing, by wet etching, the sacrificial layer and a region of the intermediate layer between the second layer and the second structural portion;
a drying step; and
a cutting step of cutting the support beam.

3. The microstructure manufacturing method according to claim 1 or 2, wherein, in the cutting step, the support beam is cut by reactive ion etching.

4. The microstructure manufacturing method according to claim 2, wherein, in the cutting step, the support beam is cut by reactive ion etching, and the first electrode and second electrode are made of a material having resistance to the reactive ion etching.

5. The microstructure manufacturing method according to claim 2 or 4, wherein the support beam is formed at a position not opposed to the second electrode.

6. The microstructure manufacturing method according to claim 2 or 4, wherein the second electrode has an opening portion, and in the formation step, the support beam is formed at a position opposing the opening portion.

7. The microstructure manufacturing method according to claim 1 or 2, wherein the support beam has a width of 0.3 to 50 μm.

8. The microstructure manufacturing method according to claim 1 or 2, wherein, prior to the cutting step, the second structural portion has a thickness of 3 μm or greater.

9. The microstructure manufacturing method according to claim 1 or 2, wherein, in the formation step, the first layer is subjected to anisotropic etching through a mask pattern for masking regions in the first layer which are to be processed to form the first structural portion, second structural portion, and support beam.

10. The microstructure manufacturing method according to claim 1 or 2, further comprising a step, prior to the formation step, of forming an etching amount adjustment film on the first layer corresponding to the region to be processed to form the support beam in the first layer, and wherein, in the formation step, the etching amount adjustment film as well as the first layer are subjected to anisotropic etching through a mask pattern for masking regions in the first layer to be processed to form the first structural portion and second structural portion.

11. The microstructure manufacturing method according to claim 10, wherein the support beam is thinner than the first structural portion and the second structural portion.

12. The microstructure manufacturing method according to claim 10, wherein the support beam has a thickness of 1 to 3 μm.

13. The microstructure manufacturing method according to claim 1 or 2, wherein the first layer comprises single-crystal silicon.

14. The microstructure manufacturing method according to claim 10, wherein the etching amount adjustment film comprises silicon oxide or silicon nitride.

15. A microstructure comprising:
a base;
a first structural portion joined to the base;
a second structural portion opposed to the base and having a fixed end fixed to the first structural portion; and
a support beam which bridges the first structural portion and second structural portion.

16. The microstructure according to claim 15, further comprising a first electrode, provided on the side of the second structural portion opposite the base, and a second electrode, joined to the first structural portion, and having a region opposing the first electrode.

17. The microstructure according to claim 15, wherein the second electrode has an opening portion at a location opposing the gap between the fixed portion and the movable portion.

18. The microstructure according to claim 15, wherein the support beam has a width of 0.3 to 50 μm.

19. The microstructure according to claim 15, wherein the support beam is thinner than the first structural portion and the second structural portion.

20. The microstructure according to claim 15, wherein the second structural portion has a maximum thickness of 3 μm or greater.
